(19) United States
(12) Patent Application Publication
(10) Pub. No.: US 2008/0227266 A1
(43) Pub. Date: Sep. 18, 2008

(54) Method of STI corner rounding using nitridation and high temperature thermal processing

(75) Inventor: Hiroaki Niimi, Austin, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/717,937

(22) Filed: Mar. 14, 2007

(51) Int. Cl. H01L 21/76

(52) U.S. Cl. 438/424

(57) ABSTRACT

One embodiment of the present invention relates to a method of forming an isolation structure with rounded corners in a semiconductor substrate, comprising forming an isolation trench within the semiconductor substrate, performing an oxidation blocking nitridation process on exposed surfaces of the trench, performing corner rounding by oxidizing the exposed surfaces after the oxidation blocking nitridation process, and filling the trench with a dielectric material.

### FIELD OF INVENTION

The present invention relates generally to semiconductor devices and more particularly to methods for shallow trench isolation corner rounding in the manufacture of semiconductor devices.

### BACKGROUND OF THE INVENTION

In the fabrication of semiconductor devices, isolation structures are formed between active areas in which electrical devices such as transistors, memory cells, or the like, are to be formed. The isolation structures, in this case shallow trench isolation (STI) structures, are typically formed during initial processing of a semiconductor substrate, prior to the formation of such electrical devices.

A MOS transistor is a basic building block, for example, wherein the transistor can be controlled to operate either in a digital or analog manner. In the fabrication of MOS transistors, source and drain regions are doped opposite that of a body region or well region in a semiconductor substrate. For example, as illustrated in prior art FIG. 1, source/drain regions 12 are formed in a semiconductor body 14 of a MOS transistor, wherein the source/drain regions 12 are an n-type material and the body region 14 is a p-type material (an NMOS transistor). A gate structure 16, for example, a polysilicon gate electrode 18 overlying a gate dielectric 20, overlies a channel region 22 of the semiconductor body. Sidewall spacers 24 reside on lateral edges of the gate structure 16 to facilitate the spacing of extension regions 26 associated with the source/drains 12. Based on the gate structure 16, a distance between the source/drain regions 12 is defined, which is often referred to as a channel length “L”, while a depth of the transistor, or extent in which the transistor extends transverse to the channel, is often referred to as a width “W” of the device

Referring to prior art FIG. 2, a portion of a partially fabricated semiconductor device 10 is illustrated, wherein a plurality of isolation structures 30, or STI structures, are formed in the semiconductor body 14, thereby separating the body into isolation regions 32 and active areas 34, respectively. Subsequently, transistor devices such as MOS transistors are formed in the active areas 34, wherein a width dimension “W” of the MOS transistors extends between the isolation structures 30 as illustrated. As MOS transistor scaling continues, the distance “W” between the isolation structures decreases. As transistor devices are scaled down to improve device density, both the width “W” and the channel length “L” dimensions are reduced, giving rise to various fabrication and device performance issues.

As illustrated in prior art FIG. 3, after source/drain regions 12 (FIG. 1) and gate structures 16 (FIG. 1) are formed in the active areas of the semiconductor device 10, defined corners 40 of the active regions near the STI trenches 30 can suffer negative effects. These STI corners 40 (FIG. 3) tend to be sharp for a zero degree rotated substrate after trench etch. These sharp features can increase stresses, produce large electric fields, create dislocations in the silicon, and ultimately fail the device, for example. Therefore, corner rounding within STI is a crucial task in order to minimize device degradation. One method to round STI corners is high temperature oxidation. However, in general, high temperature oxidation (˜1100° C.), for advanced devices requires thin STI liner layers. Therefore, it is difficult to satisfy requirements for both STI corner rounding and thin liner thickness at the same time. In other words, it is hard to grow thin oxide at the very high temperatures needed for oxidation.

FIGS. 4-7 are cross-sectional views illustrating the fabrication of the STI structure 100 illustrated in FIGS. 1-3, according to a conventional method. In FIG. 4, a pad oxide layer 104 is formed on a semiconductor substrate 102 and a subsequent nitride layer 106 is formed on the oxide layer 104, which is then patterned 110 in FIG. 5 to form STI openings 108 utilizing known photolytic processes.

Referring now to FIG. 6, the semiconductor substrate 100 is then etched 112 to form STI trenches 114 using the patterned nitride layer 106 as an etching mask. As illustrated in FIG. 6, corners 116 are created within the substrate 102, which are often referred to as trench corners 116, and in this case the corners 116 are sharp, as described supra.

Subsequently, as illustrated in FIG. 7, a liner 118 is typically formed of a thin silicon nitride on the walls of the STI trench 120. After formation of the liner 118 at the walls of the STI trench 120, the STI trench 120 is filled an insulating material 122, for example, with single or multiple isolation, low-k or dielectric materials. The STI 126 in this embodiment form what is known as an STI moat. The isolation materials 122 for the STI can be, for example silicon dioxide (SiO₂), ZrO₂, Al₂O₃, high density plasma (HDP) oxide, combinations thereof, and the like. The isolation material 122, in FIG. 7, is shown after chemical mechanical polishing 124 has taken place. The process of forming STI 126 within a substrate is well known by those of ordinary skill in the art.

The process can continue with an anneal process utilized to densify the insulating layer 122. The nitride layer 106 is removed in a subsequent act followed by a wet etch process to remove the pad oxide layer 104. Once a dielectric layer (e.g., tunnel oxide layer) is formed during subsequent steps, the resultant tunnel oxide layer is thinner near sharp corners 116. This resultant reduction in the thickness of tunnel oxide layer can result in poor tunnel oxide integrity, higher stress concentrations, increased electrical fields, leakage currents, and the like.

Turning to FIG. 8, a top view of a partial STI moat 130 fabricated using conventional techniques is illustrated showing STI(s) 126, for example. The substrate 102 is separated from the STI 126 by an STI liner 128 that separates the trench wall 132 from the STI insulation material 126. However, as illustrated in FIG. 8 and discussed supra, it is difficult to form a rounded STI liner 130. Many efforts have been undertaken to construct an STI structure 126 with a rounded corner in order to prevent the deleterious sharp corner effects mentioned supra.

There exists, therefore, a need in the semiconductor industry for an improved method to fabricate an STI structure with a rounded corner.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

One embodiment is a method of forming an isolation structure with rounded corners in a semiconductor substrate, comprising forming an isolation trench within the semiconductor substrate, performing an oxidation blocking nitridation process on exposed surfaces of the trench, performing corner rounding by oxidizing the exposed surfaces after the oxidation blocking nitridation process, and filling the trench with a dielectric material.

In yet another embodiment, a method is disclosed of forming an isolation structure with rounded corners in a semiconductor substrate, comprising forming an isolation trench within the semiconductor substrate, performing an oxidation blocking nitridation process on exposed surfaces of the trench, performing corner rounding by oxidizing the exposed surfaces after the oxidation blocking nitridation process, wherein the oxidation temperature is much greater than the oxide reflow temperature, and filling the trench with a dielectric material.

Yet another embodiment involves a method of forming an isolation structure with rounded corners in a semiconductor substrate, comprising forming an isolation trench within the semiconductor substrate, incorporating nitride atoms on exposed surfaces of the trench, performing a high temperature oxidation process after the incorporating nitride atoms, and filling the trench with a dielectric material.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1 is a simplified perspective cross sectional view illustrating a conventional semiconductor device;

FIG. 2 is a simplified cross sectional view illustrating a conventional semiconductor device with shallow trench isolation structures;

FIG. 3 is another cross sectional view of a conventional semiconductor device with shallow trench isolation structures;

FIGS. 4-7 are cross-sections of conventional STI structures at various stages in the manufacturing process;

FIG. 8 is a top view of a conventional STI illustrating the sharp corners formed during conventional processing;

FIG. 9 is a flow diagram illustrating an exemplary method of fabricating STI with rounded corners in a semiconductor substrate according to one aspect of the present invention; and

FIG. 10 is another flow diagram illustrating yet another exemplary method, according to another aspect of the present invention of forming STI with rounded corners.

### DETAILED DESCRIPTION OF THE INVENTION

The present invention will now be described with reference to the attached drawings, wherein like reference numerals are used to refer to like elements throughout. The drawings are not drawn to scale, nor are individual components within the drawings necessarily drawn in scale relative to one another. However, the method is applicable to other processes, for example, a process for forming any suitable digital or analog electronic device, for example, switches, I/O devices, logic devices, analog devices, power IC outputs, switches, inverter switches, and the like. Furthermore, while the following detailed description is presently contemplated by the inventors for practicing the invention, it should be understood that the description of this embodiment is merely illustrative and that it should not be taken in a limiting sense.

As device sizes shrink, it becomes more and more important to prevent and/or deal with wafer defects in a suitable way. One type of defect that the inventors have appreciated is STI sharp corner defects, wherein the STI that was formed in previous processing steps has sharp corners. These sharp corners/features can cause problems, for example, they can increase stresses, produce large electric fields, create dislocations in the silicon, and ultimately fail the device, for example. Therefore, creating corner rounding within STI is a crucial task in order to minimize device degradation, and the like.

In order to fully appreciate the various aspects of the present invention, a brief description of one embodiment of a semiconductor device including an STI region will be discussed. In the fabrication of semiconductor devices, isolation structures are formed between active areas in which electrical devices such as transistors, memory cells, or the like, are to be formed. The isolation structures, in this case STI structures, are typically formed during initial processing of a semiconductor substrate, prior to the formation of such electrical devices.

Many companies employ STI technology to isolate electronic devices (e.g., transistors) on an integrated circuit in order to prevent current leakage between the various devices. STI has replaced the traditional LOCOS (local oxidation of silicon) structures, in some applications due to STI providing a more controlled form of electrical isolation. LOCOS structures, in contrast, typically consume larger amounts of space because the oxidation region expands the isolation area laterally in proportion to the depth of the isolation.

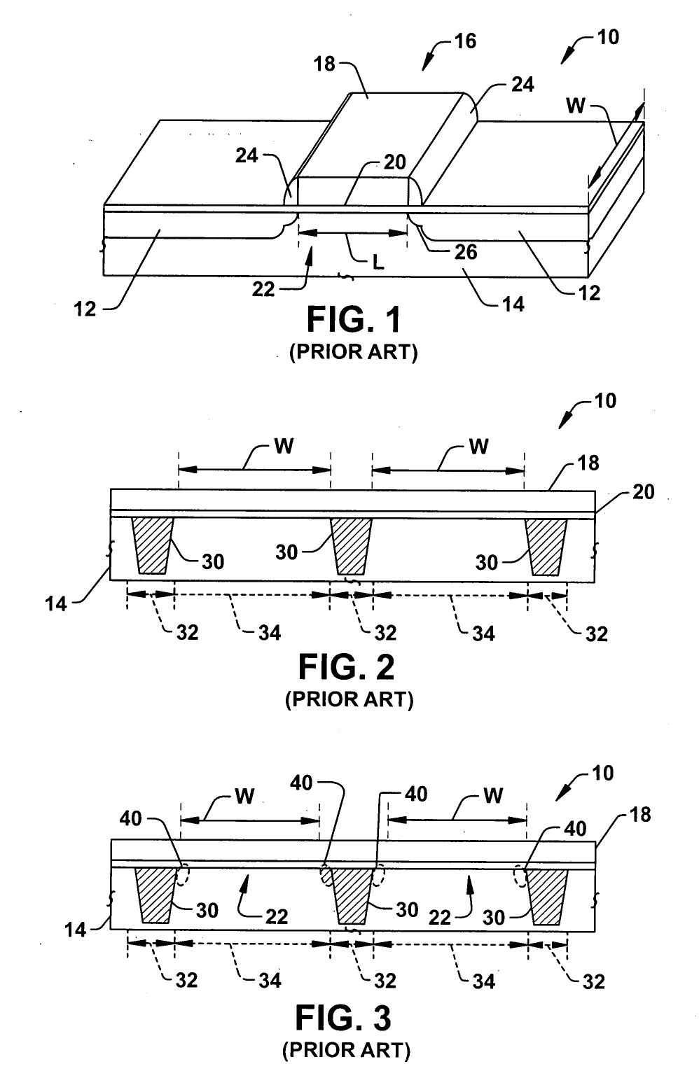

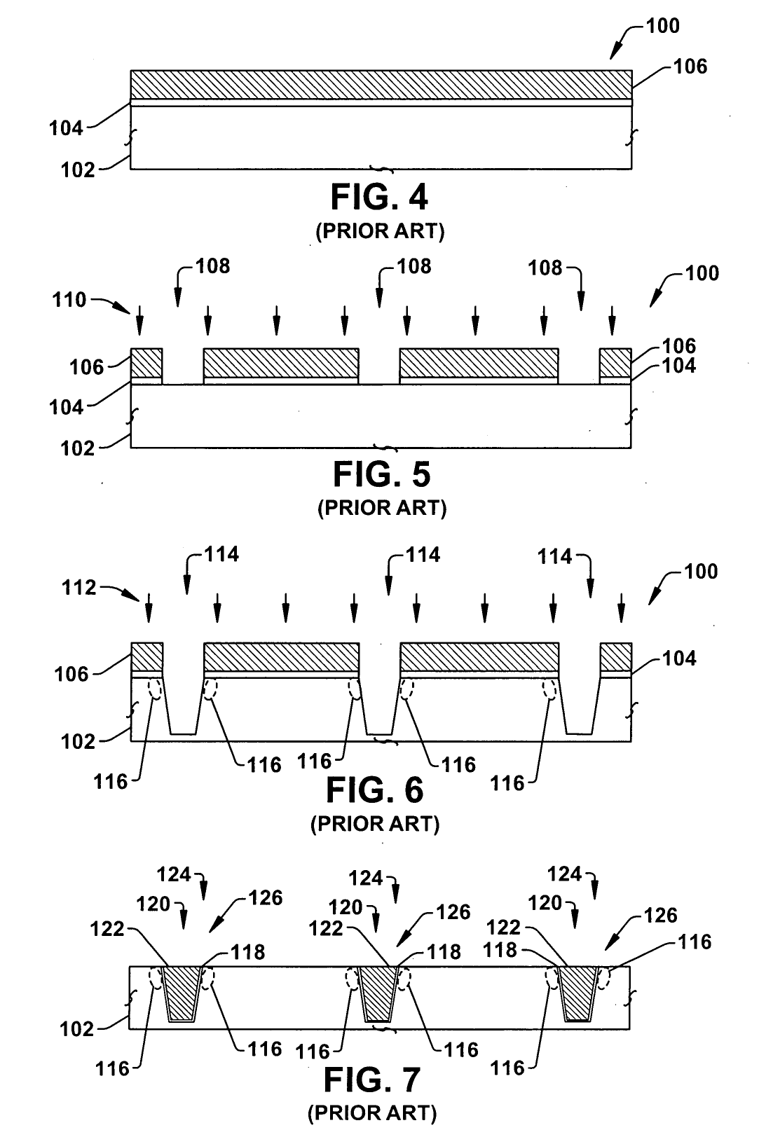

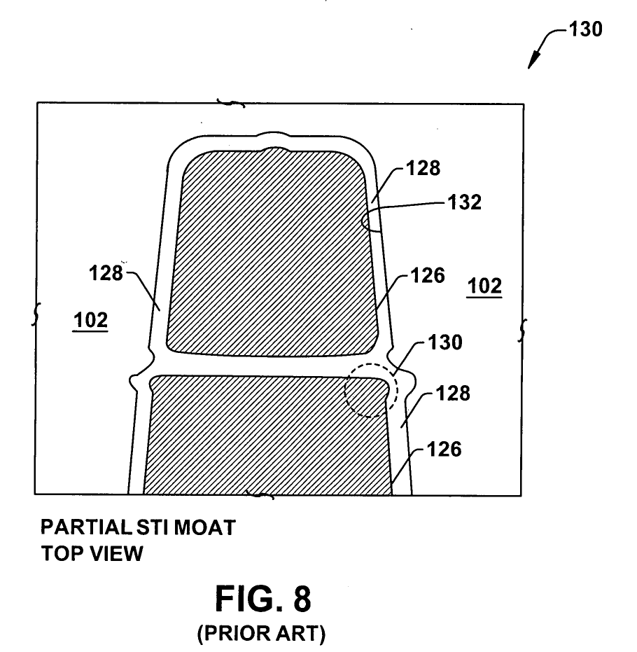

While the methods illustrated herein are illustrated and described as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the operation of devices which are illustrated and described herein (e.g., device 100 in FIG. 1) as well as in association with other devices not illustrated, wherein all such implementations are contemplated as falling within the scope of the present invention and the appended claims.

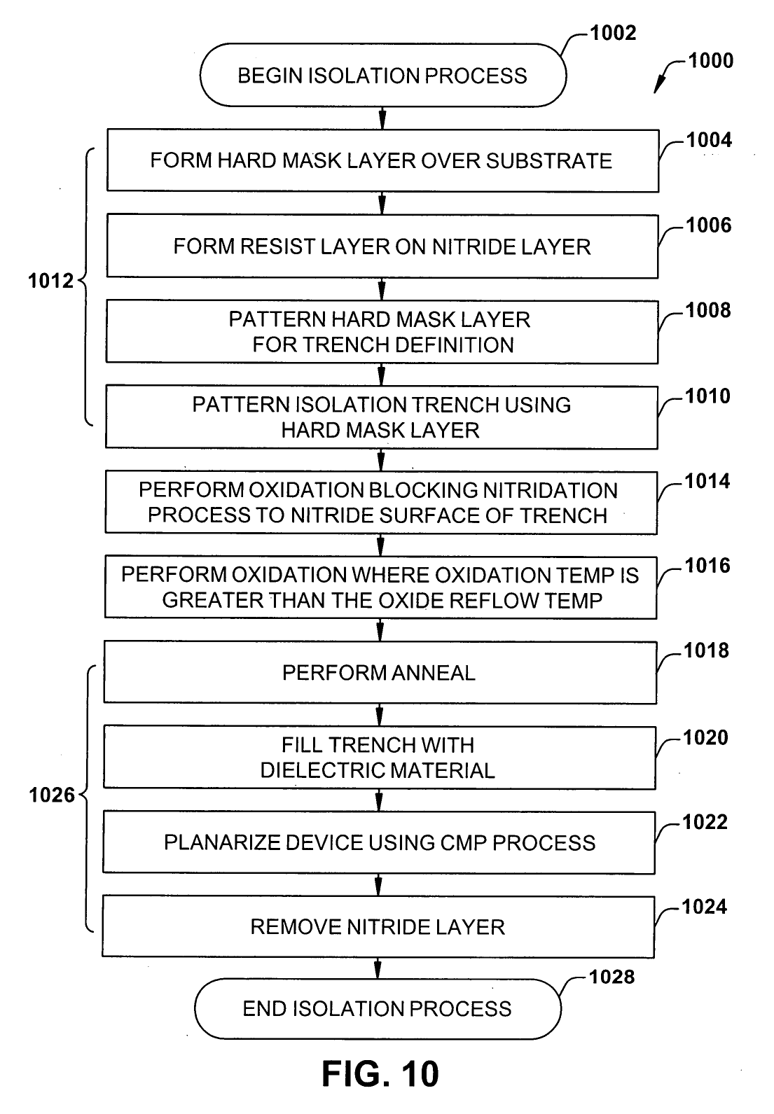

Referring to FIG. 10, an exemplary method 1000 is illustrated for fabricating an STI with rounded corners in a substrate in accordance with one or more aspects of the present invention. It will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated herein.

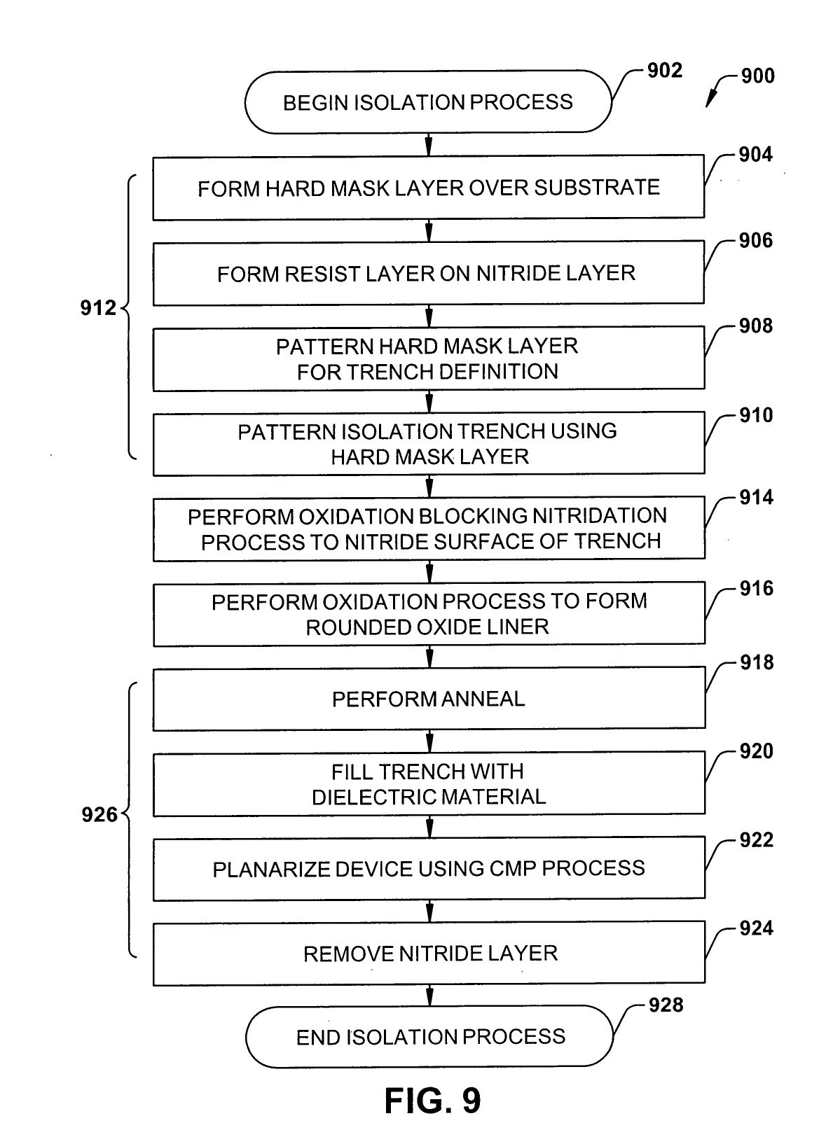

Beginning at 902 of FIG. 9, a substrate is provided with active regions created per ion implantation, for example at 902. It will be appreciated that the implantation process can take place at various times along the process as is well known to those of ordinary skill in the art. At 904 an oxide layer is formed over the substrate utilizing a thermal oxide process. Any appropriate process steps and materials can be employed in the formation of the oxide layer at 904, including oxidation processes as are well known to those of ordinary skill in the art.

Additionally at 904 a nitride layer is formed over the oxide layer at 904. Known deposition processes by those of ordinary skill in the art can be employed in the formation of the nitride layer at 904. The nitride layer, can be, for example, silicon nitride, reaction bonded silicon nitride, hot pressed silicon nitride, sintered silicon nitrides, and the like. The oxide layer and the nitride layer are referred to as a hard mask. At 906 active areas of substrate are coated with a photoresist and subsequently exposed to light through openings in a photoresist mask, for example. The photoresist can be, for example, a solvent-based, light sensitive resin solution that softens or becomes soluble when exposed to light (positive photoresist). Any appropriate process steps, materials or energy may be utilized in forming the photolytic mask and exposing the photoresist.

The methodology continues at 908, where a soluble photoresist (exposed or un-exposed), for example is developed or etched away exposing the outer surface of the nitride layer at 908. The process at 910 results in a pattern being formed on the substrate allowing for trench formation. At 910 a nitride layer and oxide layer etching process can be performed. The STI trench can be formed in those areas where the photoresist was removed at 908. Any suitable fabrication steps or materials can be employed in etching the oxide and nitride layers as are known, for example, wet etching techniques, or dry etching techniques, or both. At 910 the trench can be created in the substrate. The etching procedure may be, for example, a single step or multi-step process, a wet or dry etch process, by which material is removed in the exposed isolation regions in the semiconductor substrate to form the isolation trenches.

In addition, at 910 the photoresist is removed. The process of removing photoresist is well known by those of ordinary skill in the art. The processes 904, 906, 908 and 910 can be referred to collectively as front end processing 912. The exemplary method 900 continues at 914, for example, with the deposition or forming of an oxidation blocking nitridation process on exposed surfaces of the STI trench. The oxidation blocking nitridation layer can be deposited or formed in any suitable process, such as, a thermal growth process at the exposed trench surfaces, including the sidewall recesses and the center section of the etched STI trench. As discussed supra, the nitridation layer can be deposited to act as a protective blocking layer or STI liner at the exposed surfaces of trench, and the like. The trench lining nitridation process can be, for example, a plasma process employed at a pressure of between about 10 and 75 mTorr, an RF power of between about 500 to 1000 Watts, and a N₂ flow rate of about 50 to 500 standard cubic centimeters per minute.

In an alternate embodiment at 914 the nitration process can be a plasma nitration process performed at a pressure of between about 50 to 200 mTorr, a power of about 1000 to 1500 Watts, a temperature of between about 300 to 500 degrees Celsius, an N₂ flow rate of about 50 to 500 standard cubic centimeters per minute and an Ar flow rate of about 800 to 1200 standard cubic centimeters per minute. In yet another embodiment of the present invention at 914 the nitridation process is a thermal process performed at a pressure of between about 300 to 760 Torr, a temperature of between about 500 to 900 degrees Celsius, and between about 1 to 3 standard liters per minute of NH₃.

At 916 of FIG. 9 an oxidation process is performed to round the corners of the STI liner formed at 914. In one embodiment, the oxidation process is an in-situ steam generation (ISSG) process performed at a temperature of between about 1050 to 1150 degrees Celsius, a pressure of between about 5 to 10 Torr, and a gas atmosphere of about 5% to 15% H₂ in O₂. In another embodiment, the oxidation process is performed at a temperature of between about 1050 to 1150 degrees Celsius, a pressure of between about 100 to 300 Torr, and an N₂O gas. It should be apparent to those of ordinary skill in the art that other trench liner materials (e.g., nitride), multiple isolation liners, no liners at all, and the like are contemplated with this invention.

The exemplary method 900 continues at 918, for example, with an anneal/repair process performed, according to another embodiment of the present invention. The annealing techniques are widely known in the present art by those of ordinary skill. At 920 the trench can then be filled with a gap-filling oxide isolation material. The structure is subsequently chemically mechanically polished (CMP) at 922 to create a planar STI structure such that electrical devices (inner active areas) can be formed within regions bounded by the STI. The nitride layer is removed at 924 using techniques known by those of ordinary skill in the art. It should be appreciated that any process known by those of ordinary skill in the art to remove the nitride layer is contemplated with this invention. The isolation nitride, for example, can be removed with phosphoric acid at elevated temperature and SC1 megasonic processing. The processes in 918 through 924 can be referred to as back end processing 926. The isolation process 900 ends at 928.

Referring now to FIG. 10, an exemplary method 1100 is illustrated for fabricating an STI with rounded corners in a substrate in accordance with one or more aspects of the present invention. It will be once again appreciated that the present invention is not restricted by the illustrated ordering of acts or events. Some acts or events may occur in different orders and/or concurrently with other acts or events apart from those illustrated and/or described herein, in accordance with the invention. In addition, not all illustrated acts or events may be required to implement a methodology in accordance with the present invention. Furthermore, the methods according to the present invention may be implemented in association with the formation and/or processing of structures illustrated and described herein as well as in association with other structures not illustrated.

Beginning at 1002 of FIG. 10, a substrate is provided with active regions created per ion implantation, for example at 1002. At 1004 a hard mask is formed over the substrate. At 1006 a photoresist mask, for example, is formed on the nitride layer formed as part of the hard mask at 1004. The methodology continues at 1008, where the photoresist is patterned using techniques well known by those of ordinary skill in the art. The process at 1010 results in a pattern being formed on the substrate allowing for trench formation. The STI trench can be formed in those areas where the photoresist was removed. Any suitable fabrication steps or materials can be employed in forming the trenches and any techniques discussed supra. The processes 1004, 1006, 1008 and 1010 can be referred to collectively as front end processing 1012.

A nitridation layer can be deposited or formed in any suitable process, such as, a thermal growth process at the exposed trench surfaces. As discussed supra, the nitridation layer can be deposited to act as a protective blocking layer or STI liner at the exposed surfaces of trench, and the like. The trench lining nitridation process can be, for example, a plasma process employed at a pressure of between about 10 and 75 mTorr, an RF power of between about 500 to 1000 Watts, and a N₂ flow rate of about 50 to 500 standard cubic centimeters per minute.

In an alternate embodiment at 1014 the nitration process can be performed at a pressure of between about 50 to 200 mTorr, a power of about 1000 to 1500 Watts, a temperature of between about 300 to 500 degrees Celsius, a N₂ flow rate of about 50 to 500 standard cubic centimeters per minute and an Ar flow rate of about 800 to 1200 standard cubic centimeters per minute. In yet another embodiment of the present invention at 1014 the nitridation process is a thermal performed at a pressure of between about 300 to 760 Torr, a temperature of between about 500 to 900 degrees Celsius, and between about 1 to 3 standard liters per minute of NH₃.

At 1016 of FIG. 10 a high temperature oxidation process is performed to round the corners of the STI liner formed at 1014. In one embodiment, the oxidation process is an oxidation process performed at a temperature equal to or greater than 1050 degrees Celsius, a pressure of between about 5 to 10 Torr, and a gas atmosphere of about 5% to 15% H₂ in O₂. In another embodiment, the oxidation process is performed at a temperature equal to or greater than 1050 degrees Celsius, a pressure of between about 100 to 300 Torr, and an N₂O gas. It should be apparent to those of ordinary skill in the art that other trench liner materials (e.g., nitride), multiple isolation liners, no liners at all, and the like are contemplated with this invention.

The exemplary method 1000 continues at 1018, for example, with an anneal/repair process performed, according to another embodiment of the present invention. The repair techniques are widely known in the present art by those of ordinary skill. At 1020 the trench can then be filled with a gap-filling oxide isolation material. The structure is subsequently chemically mechanically polished (CMP) at 1022 to create a planar STI structure such that electrical devices (inner active areas) can be formed within regions bounded by the STI, often referred to as moats. The nitride layer is removed at 1024 using techniques known by those of ordinary skill in the art. It should be appreciated that any process known by those of ordinary skill in the art to remove the nitride layer is contemplated with this invention. The isolation nitride, for example, can be removed with phosphoric acid at elevated temperature and SC1 megasonic processing. The processes in 1018 through 1024 can be referred to as back end processing 1026. The isolation process 1000 ends at 1028.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising.”

What is claimed is:

1. A method of forming an isolation structure with rounded corners in a semiconductor substrate, comprising:
forming an isolation trench within the semiconductor substrate;
performing an oxidation blocking nitridation process on exposed surfaces of the trench;
performing corner rounding by oxidizing the exposed surfaces after the oxidation blocking nitridation process; and
filling the trench with a dielectric material.

2. The method of claim 1, wherein the oxidation process is an in-situ steam generation process performed at a temperature of between about 1050 to 1150 degrees Celsius, a pressure of between about 5 to 10 Torr, and a gas atmosphere of about 5% to 15% H₂ in O₂.

3. The method of claim 2, wherein the nitration process is performed at a pressure of between about 10 to 75 mTorr, an RF power of about 500 to 1000 Watts, and an N₂ flow rate of about 50 to 500 standard cubic centimeters per minute.

4. The method of claim 2, wherein the nitration process is performed at a pressure of between about 50 to 200 mTorr, a power of about 1000 to 1500 Watts, a temperature of between about 300 to 500 degrees Celsius, an N₂ flow rate of about 50 to 500 standard cubic centimeters per minute and an Ar flow rate of about 800 to 1200 standard cubic centimeters per minute.

5. The method of claim 2, wherein the nitridation process is performed at a pressure of between about 300 to 760 Torr, a temperature of between about 500 to 900 degrees Celsius, and about 1 to 3 standard liters per minute of NH₃.

6. The method of claim 1, wherein the oxidation process is performed at a temperature of between about 1050 to 1150 degrees Celsius, a pressure of between about 100 to 300 Torr, and an N₂O gas.

7. The method of claim 6, wherein the nitration process is performed at a pressure of between about 10 to 75 mTorr, an RF power of about 500 to 1000 Watts, and an N₂ flow rate of about 50 to 500 standard cubic centimeters per minute.

8. The method of claim 6, wherein the nitration process is performed at a pressure of between about 50 to 200 mTorr, a power of about 1000 to 1500 Watts, a temperature of between about 300 to 500 degrees Celsius, an N₂ flow rate of about 50 to 500 standard cubic centimeters per minute and an Ar flow rate of about 800 to 1200 standard cubic centimeters per minute.

9. The method of claim 6, wherein the nitridation process is performed at a pressure of between about 300 to 760 Torr, a temperature of between about 500 to 900 degrees Celsius, and about 1 to 3 standard liters per minute of NH₃

10. A method of forming an isolation structure with rounded corners in a semiconductor substrate, comprising:
forming an isolation trench within the semiconductor substrate;
performing an oxidation blocking nitridation process on exposed surfaces of the trench;
performing corner rounding by oxidizing the exposed surfaces after the oxidation blocking nitridation process;
wherein the oxidation temperature is greater than the oxide reflow temperature; and
filling the trench with a dielectric material.

11. The method of claim 10, wherein the oxidation process is an in-situ steam generation process performed at a temperature of between about 1050 to 1150 degrees Celsius, a pressure of between about 5 to 10 Torr, and a gas atmosphere of about 5% to 15% H₂ in O₂; or wherein the oxidation process is performed at a temperature of between about 1050 to 1150 degrees Celsius, a pressure of between about 100 to 300 Torr, and an N₂O gas.

12. The method of claim 11, wherein the nitration process is performed at a pressure of between about 10 to 75 mTorr, an RF power of about 500 to 1000 Watts, and an N₂ flow rate of about 50 to 500 standard cubic centimeters per minute.

13. The method of claim 11, wherein the nitration process is performed at a pressure of between about 50 to 200 mTorr, a power of about 1000 to 1500 Watts, a temperature of between about 300 to 500 degrees Celsius, an N₂ flow rate of about 50 to 500 standard cubic centimeters per minute and an Ar flow rate of about 800 to 1200 standard cubic centimeters per minute.

14. The method of claim 11, wherein the nitridation process is performed at a pressure of between about 300 to 760 Torr, a temperature of between about 500 to 900 degrees Celsius, and about 1 to 3 standard liters per minute of NH₃.

15. The method of claim 10, wherein the nitridation process is performed at a pressure of between about 300 to 760 Torr, a temperature of between about 500 to 900 degrees Celsius, and about 1 to 3 standard liters per minute of NH₃.

16. A method of forming an isolation structure with rounded corners in a semiconductor substrate, comprising:
forming an isolation trench within the semiconductor substrate;
incorporating nitride atoms on exposed surfaces of the trench;
performing a high temperature oxidation process after the incorporating nitride atoms; and
filling the trench with a dielectric material.

17. The method of claim 16, wherein the high temperature oxidation process takes place at a temperature greater than 1050 degrees Celsius.

18. The method of claim 16, wherein the concentration of the nitrogen atoms is approximately about 1.0×10¹⁶ cm².

19. The method of claim 16, wherein the incorporating nitride atoms is accomplished utilizing plasma or thermal nitridation.

20. The method of claim 16, wherein the oxidation time is about 45 to 90 seconds.
